(19) United States
(12) Patent Application Publication
(10) Pub. No.: US 2015/0048360 A1
(43) Pub. Date: Feb. 19, 2015

(54) SEMICONDUCTOR DEVICE AND SEMICONDUCTOR DEVICE MANUFACTURING METHOD

(71) Applicant: Sharp Kabushiki Kaisha, Osaka (JP)

(72) Inventor: Katsunori Misaki, Yonago-shi (JP)

(73) Assignee: Sharp Kabushiki Kaisha, Osaka (JP)

(21) Appl. No.: 14/385,960

(22) PCT Filed: Mar. 11, 2013
(86) PCT No.: PCT/JP2013/056664

§ 371 Date: Sep. 17, 2014

(30) Foreign Application Priority Data
Mar. 21, 2012 (JP) 2012-063745

(51) Int. Cl. H01L 27/12; H01L 21/02

(52) U.S. Cl. CPC H01L 27/1255; H01L 27/1225; H01L 27/1259; H01L 21/02565
USPC 257/43; 438/104

(57) ABSTRACT

A semiconductor device includes a substrate, a TFT supported by the substrate, an auxiliary capacitor, a source wiring line, and a gate wiring line. The auxiliary capacitor has a first auxiliary capacitor electrode, a second auxiliary capacitor electrode, and a first insulating layer. When viewed from the direction normal to the substrate, the gate wiring line and the source wiring line overlap to form a gate-source intersection region in which the first insulating layer and a second insulating layer are formed. The distance between the first auxiliary capacitor electrode and the second auxiliary capacitor electrode is smaller than the distance between the gate wiring line and the source wiring line in the gate-source intersection region.

### TECHNICAL FIELD

The present invention relates to a semiconductor device provided with a thin film transistor and a method of manufacturing the same.

### BACKGROUND ART

In general, an active matrix type liquid crystal display device has a substrate (hereinafter, TFT substrate) having a thin film transistor (hereinafter, also called TFT) formed thereon as a switching element for each pixel, an opposite substrate having color filters and the like formed thereon, and a liquid crystal layer provided between the TFT substrate and the opposite substrate. The TFT substrate has the TFT and an auxiliary capacitance. An auxiliary capacitance is a capacitance provided electrically parallel to the liquid crystal capacitance for maintaining a voltage applied to the liquid crystal layer (known as liquid crystal capacitance in the field of electricity) of the pixel. In the present specification, a TFT substrate or a display device provided with a TFT substrate may be referred to as a semiconductor device.

Recently, the use of an oxide semiconductor to form an active layer of the TFT instead of a silicon semiconductor is being proposed. Such a TFT is referred to as an “oxide semiconductor TFT.” Oxide semiconductors have a higher mobility than amorphous silicon. Therefore, the oxide semiconductor TFT can operate at a faster speed than the amorphous silicon TFT. Patent Document 1 discloses an active matrix type liquid crystal display device using the oxide semiconductor TFT as a switching element, for example (Patent Document 1, for example). Furthermore, the oxide semiconductor TFT disclosed in Patent Document 1 has an etching stopper layer over the oxide semiconductor layer so as to protect the channel region of the oxide semiconductor layer.

### RELATED ART DOCUMENT

### Patent Document

Patent Document 1: Japanese Patent Application Laid-Open Publication No. 2011-191764

### SUMMARY OF THE INVENTION

### Problems to be Solved by the Invention

As mentioned above, if an etching stopper layer is formed on the oxide semiconductor layer, then the channel region of the oxide semiconductor layer can be protected. However, according to studies by the inventor of the present invention, when an etching stopper layer is formed, the following problems occur regarding the auxiliary capacitance.

FIG. 18 is a schematic cross-sectional view of a portion that includes an auxiliary capacitance unit 500 of a TFT substrate that has a TFT with an etching stopper layer 61. The auxiliary capacitance unit 500 shown in FIG. 18 has a lower auxiliary capacitance electrode 56 formed on a substrate 1 and an upper auxiliary capacitance electrode 58 formed so as to oppose the lower auxiliary capacitance electrode 56 with a dielectric layer DL therebetween. Here, the dielectric layer DL is formed of a gate insulating layer 57 and an etching stopper layer 61. The example shown has a gate insulating layer 57 having two layers of gate insulating layers 57a and 57b, but the gate insulating layer 57 naturally can have one layer. A protective layer 63 is formed over the gate insulating layer 57, and a pixel electrode 71 is formed over the protective layer 63.

The upper auxiliary capacitance electrode 58 and the pixel electrode 71 are electrically connected, and the upper auxiliary capacitance electrode 58 is supplied the same voltage (signal voltage, source voltage) as the pixel electrode 71. The lower auxiliary capacitance electrode 56 is supplied the same voltage (opposite voltage, common voltage) as the opposite electrode. The dielectric layer DL with the auxiliary capacitance unit 500 has the etching stopper layer 61 in addition to the gate insulating layer 57, and thus a thickness L of the dielectric layer DL becomes greater due to the added thickness. As a result, the capacitance value (capacitance) of the auxiliary capacitance unit 500 becomes smaller.

If the capacitance value of the auxiliary capacitance is small, then the feedthrough voltage (pulling voltage) becomes larger, and as is well-known, can cause screen burn-in or flickering.

Accordingly, the embodiments of the present invention are directed to provide a semiconductor device with an oxide semiconductor TFT that has an etching stopper layer that prevents a decrease in the auxiliary capacitance value, and a method of manufacturing the semiconductor device.

### Means for Solving the Problems

A semiconductor device of an embodiment of the present invention includes: a substrate; and a thin film transistor, an auxiliary capacitance unit, a source wiring line, and a gate wiring line that are supported by the substrate, wherein the thin film transistor includes: a gate electrode formed of a same conductive film as the gate wiring line; a first insulating layer formed on the gate electrode; an oxide semiconductor layer formed on the first insulating layer; a second insulating layer that is formed on the oxide semiconductor layer and that is in contact with a channel region of the oxide semiconductor layer; and a source electrode and a drain electrode that are formed of a same conductive film as the source wiring line and that are electrically connected to the oxide semiconductor layer, wherein the auxiliary capacitance unit includes: a first auxiliary capacitance electrode formed of the same conductive film as the gate wiring line; a second auxiliary capacitance electrode formed of the same conductive film as the source wiring line; and the first insulating layer positioned between the first auxiliary capacitance electrode and the second auxiliary capacitance electrode, wherein the first insulating layer and the second insulating layer are formed between the gate wiring line and the source wiring line at a gate/source intersection where the gate wiring line and the source wiring line overlap in a direction normal to the substrate, and wherein a distance between the first auxiliary capacitance electrode and the second auxiliary capacitance electrode is shorter than a distance between the gate wiring line and the source wiring line at the gate/source intersection.

In an embodiment, the semiconductor device mentioned above further includes an oxide layer formed of a same oxide film as the oxide semiconductor layer, below the second auxiliary capacitance electrode, wherein the oxide layer and the second auxiliary capacitance electrode are in contact with each other.

In an embodiment, the distance between the first auxiliary capacitance electrode and the second auxiliary capacitance electrode is shorter than a distance between the gate electrode and the oxide semiconductor layer.

In an embodiment, the semiconductor device mentioned above further includes another insulating layer between the gate wiring line and the source wiring line at the gate/source intersection.

In an embodiment, the oxide semiconductor layer includes an In—Ga—Zn—O semiconductor.

A method of manufacturing a semiconductor device according to one embodiment of the present invention is a method of manufacturing a semiconductor device provided with a thin film transistor and an auxiliary capacitance, including: (A) forming a gate electrode and a first auxiliary capacitance electrode of a same conductive film over a substrate; (B) forming a first insulating layer over the gate electrode and the first auxiliary capacitance electrode; (C) forming an oxide semiconductor layer over the first insulating layer so as to overlap the gate electrode when seen in a direction normal to the substrate; (D) forming a second insulating layer having a first opening that overlaps the first auxiliary capacitance electrode when seen from the direction normal to the substrate and a second opening that exposes a portion of the oxide semiconductor layer, by forming an insulating film over the oxide semiconductor layer and the first insulating layer and etching a portion of the first insulating layer and the insulating film; and (E) forming a source electrode, a drain electrode, and a second auxiliary capacitance electrode of the same conductive film, the second auxiliary capacitance electrode being formed in the first opening, the step (E) including a step of electrically connecting the source electrode and the drain electrode to the oxide semiconductor layer in the second opening.

A method of manufacturing a semiconductor device according to one embodiment of the present invention is a method of manufacturing a semiconductor device provided with a thin film transistor and an auxiliary capacitance, including: (A) forming a gate electrode and a first auxiliary capacitance electrode of a same conductive film, over a substrate; (B) forming a first insulating layer over the gate electrode and the first auxiliary capacitance electrode; (C) forming an oxide semiconductor layer and an oxide layer of a same oxide film, the oxide semiconductor layer being formed over the first insulating layer so as to overlap the gate electrode when seen in a direction normal to the substrate, the oxide layer being formed over the first insulating layer so as to overlap the first auxiliary capacitance electrode when seen in the direction normal to the substrate; (D) forming a second insulating layer having a first opening that exposes the oxide layer and a second opening that exposes a portion of the oxide semiconductor layer; and (E) forming a source electrode, a drain electrode, and a second auxiliary capacitance electrode of a same conductive film, the second auxiliary capacitance electrode being formed over the oxide layer in the first opening, the step (E) including a step of electrically connecting the source electrode and the drain electrode to the oxide semiconductor layer in the second opening.

In an embodiment, the oxide semiconductor layer includes an In—Ga—Zn—O semiconductor.

### Effects of the Invention

The embodiments of the present invention provide a semiconductor device having an etching stopper layer that prevents the auxiliary capacitance value from dropping, and the method of manufacturing the semiconductor device.

### BRIEF DESCRIPTION OF THE DRAWINGS

FIG. 1 is a schematic plan view of a semiconductor device (TFT substrate) 1000A of an embodiment of the present invention.

FIG. 2(a) is a schematic cross-sectional view of a TFT 100A along the line A-A′ of FIG. 1, FIG. 2(b) is a schematic cross-sectional view of a gate/source intersection 200A along the line B-B′ of FIG. 1, FIG. 2(c) is a schematic cross-sectional view of an auxiliary capacitance unit 300A along the line C-C′ of FIG. 1, and FIG. 2(d) is a schematic cross-sectional view of a gate terminal 400A along the line D-D′ of FIG. 1.

FIGS. 3(a1) to FIG. 3(e1) are schematic cross-sectional views explaining a method of manufacturing a TFT 100A, FIGS. 3(a2) to 3(e2) are schematic cross-sectional views that explain a method of forming a gate/source intersection 200A, FIGS. 3(a3) to 3(e3) are schematic cross-sectional views that explain a method of forming the auxiliary capacitance unit 300A, and FIGS. 3(a4) to 3(e4) are schematic plan views that explain a method of forming the gate terminal 400A.

FIG. 4(a1) is a schematic cross-sectional view describing a method of manufacturing a TFT 100A, FIG. 4(a2) is a schematic cross-sectional view describing a method of forming a gate/source intersection 200A, FIG. 4(a3) is a schematic cross-sectional view describing a method of forming an auxiliary capacitance unit 300A, and FIG. 4(a4) is a schematic cross-sectional view describing a method of forming a gate terminal 400A.

FIG. 5 is a schematic plan view of a semiconductor device (TFT substrate) 1000B of another embodiment of the present invention.

FIG. 6(a) is a schematic cross-sectional view of a TFT 100B along the line A-A′ of FIG. 5, FIG. 6(b) is a schematic cross-sectional view of a gate/source intersection 200B along the line B-B′ of FIG. 5, FIG. 6(c) is a schematic cross-sectional view of an auxiliary capacitance unit 300B along the line C-C′ of FIG. 5, and FIG. 6(d) is a schematic cross-sectional view of a gate terminal 400B along the line D-D′ of FIG. 5.

FIGS. 7(a1) to 7(c1) are schematic cross-sectional views describing a method of manufacturing a TFT 100B, FIGS. 7(a2) to 7(c2) are schematic cross-sectional views describing the method of forming a gate/source intersection 200B, FIGS. 7(a3) to 7(c3) are schematic cross-sectional views describing a method of forming a gate/source intersection, and FIGS. 7(a4) to 7(c4) are schematic plan views describing a method of forming a gate terminal 400B.

FIG. 8(a1) is a schematic cross-sectional view describing a method of manufacturing a TFT 100B, FIG. 8(a2) is a schematic cross-sectional view describing a method of forming a gate/source intersection 200B, FIG. 8(a3) is a schematic cross-sectional view describing a method of forming an auxiliary capacitance unit 300B, and FIG. 8(a4) is a schematic cross-sectional view describing a method of forming a gate terminal 400B.

FIG. 9 is a schematic plan view of a semiconductor device (TFT substrate) 1000C of yet another embodiment of the present invention.

FIG. 10(a) is a schematic cross-sectional view of a TFT 100C along the line A-A′ of FIG. 9, FIG. 10(b) is a schematic cross-sectional view of a gate/source intersection 200C along the line B-B′ of FIG. 10, FIG. 10(c) is a schematic cross-sectional view of an auxiliary capacitance unit 300C along the line C-C′ of FIG. 9, and FIG. 10(d) is a schematic cross-sectional view of a gate terminal 400C along the line D-D′ of FIG. 9.

FIGS. 11(a1) to 11(c1) are schematic cross-sectional views describing a method of manufacturing a TFT 100C, FIGS. 11(a2) to 11(c2) are schematic cross-sectional views describing a method of forming a gate/source intersection 200C, FIGS. 11(a3) to 11(c3) are schematic cross-sectional views describing a method of forming an auxiliary capacitance unit 300C, and FIGS. 11(a4) to 11(c4) are schematic plan views that describe a method of forming a gate terminal 400C.

FIGS. 12(a1) to 12(d1) are schematic cross-sectional views describing a method of manufacturing a TFT 100C, FIGS. 12(a2) to 12(d2) are schematic cross-sectional views describing a method of forming a gate/source intersection 200C, FIGS. 12(a3) to 12(d3) are schematic cross-sectional views describing a method of forming an auxiliary capacitance unit 300C, and FIGS. 12(a4) to 12(d4) are schematic plan views describing a method of forming a gate terminal 400C.

FIGS. 13(a1) and 13(b1) are schematic cross-sectional views describing a method of manufacturing a TFT 100C, FIGS. 13(a2) and 13(b2) are schematic cross-sectional views describing a method of forming a gate/source intersection 200C, FIGS. 13(a3) and 13(b3) are schematic cross-sectional views describing a method of forming an auxiliary capacitance unit 300C, and FIGS. 13(a4) and 13(b4) are schematic cross-sectional views describing a method of forming a gate terminal 400C.

FIG. 14 is a schematic plan view of a semiconductor device (TFT substrate) 1000D of yet another embodiment of the present invention.

FIG. 15(a) is a schematic cross-sectional view of a TFT 100D along the line A-A′of FIG. 14, FIG. 15(b) is a schematic cross-sectional view of a gate/source intersection 200D along the line B-B′ of FIG. 10, FIG. 10(c) is a schematic cross-sectional view of an auxiliary capacitance unit 300D along the line C-C′ of FIG. 15, and FIG. 15(d) is a schematic cross-sectional view of a gate terminal 400D along the line D-D′ of FIG. 15.

FIGS. 16(a1) to 16(d1) are schematic cross-sectional views describing a method of manufacturing a TFT 100D, FIGS. 16(a2) to 16(d2) are schematic cross-sectional views describing a method of forming a gate/source intersection 200D, FIGS. 16(a3) to 16(d3) are schematic cross-sectional views describing a method of forming an auxiliary capacitance unit 300D, and FIGS. 16(a4) to 16(d4) are schematic plan views describing a method of forming a gate terminal 400D.

FIGS. 17(a1) and 17(b1) are schematic cross-sectional views describing a method of manufacturing a TFT 100D, FIGS. 17(a2) and 17(b2) are schematic cross-sectional views describing a method of forming a gate/source intersection 200D, FIGS. 17(a3) and 17(b3) are schematic cross-sectional views describing a method of forming an auxiliary capacitance unit 300D, and FIGS. 17(a4) and 17(b4) are schematic cross-sectional views describing a method of forming a gate terminal 400D.

FIG. 18 is a schematic cross-sectional view of an auxiliary capacitance unit 500.

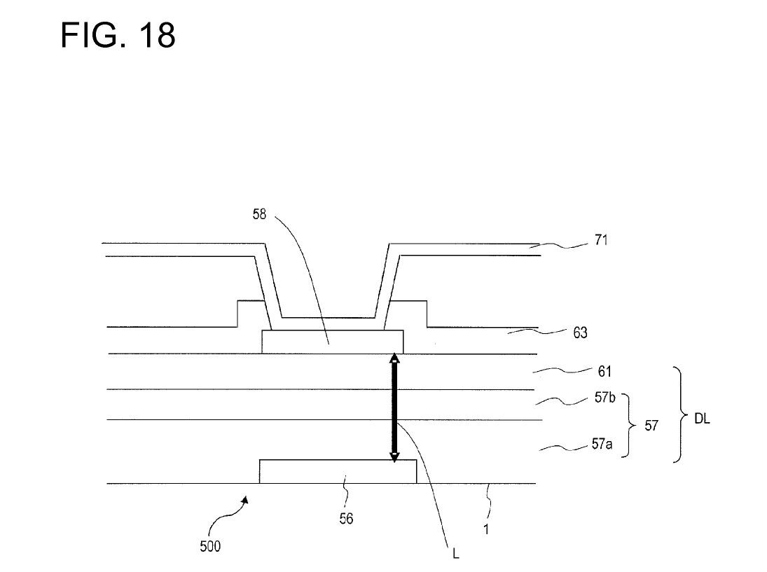

### DETAILED DESCRIPTION OF EMBODIMENTS

Below, embodiments of the present invention of a semiconductor device and a manufacturing method of the semiconductor device will be explained with reference to figures. However, the scope of the present invention is not limited to the embodiments below.

An embodiment of a semiconductor device of the present invention is a TFT substrate using an active matrix type liquid crystal display device. Furthermore, the semiconductor device of the present embodiment includes a wide range of TFT substrates that are used in various display devices, electronic devices, and the like other than liquid crystal display devices.

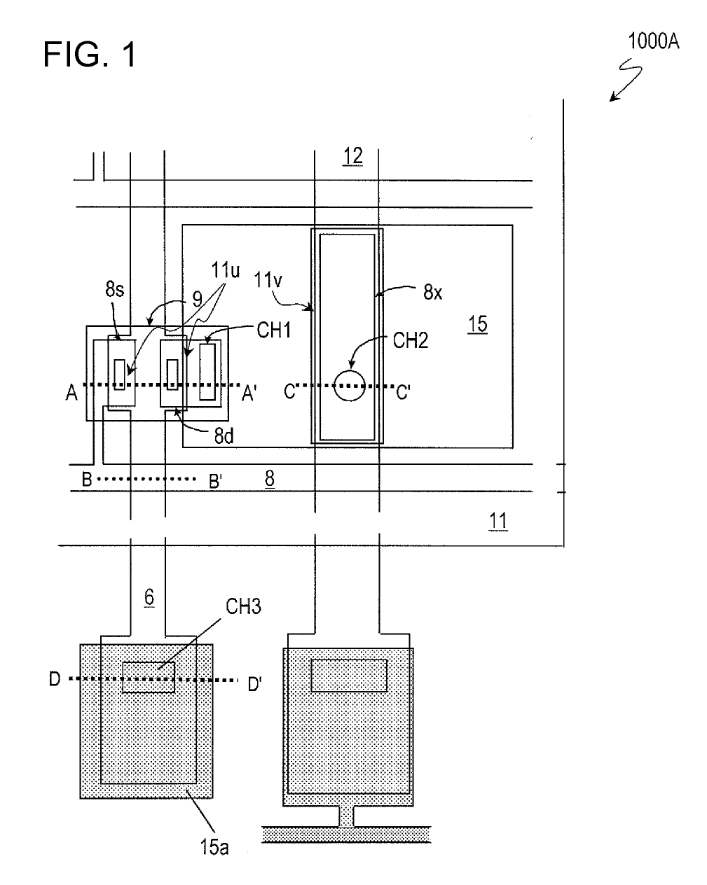

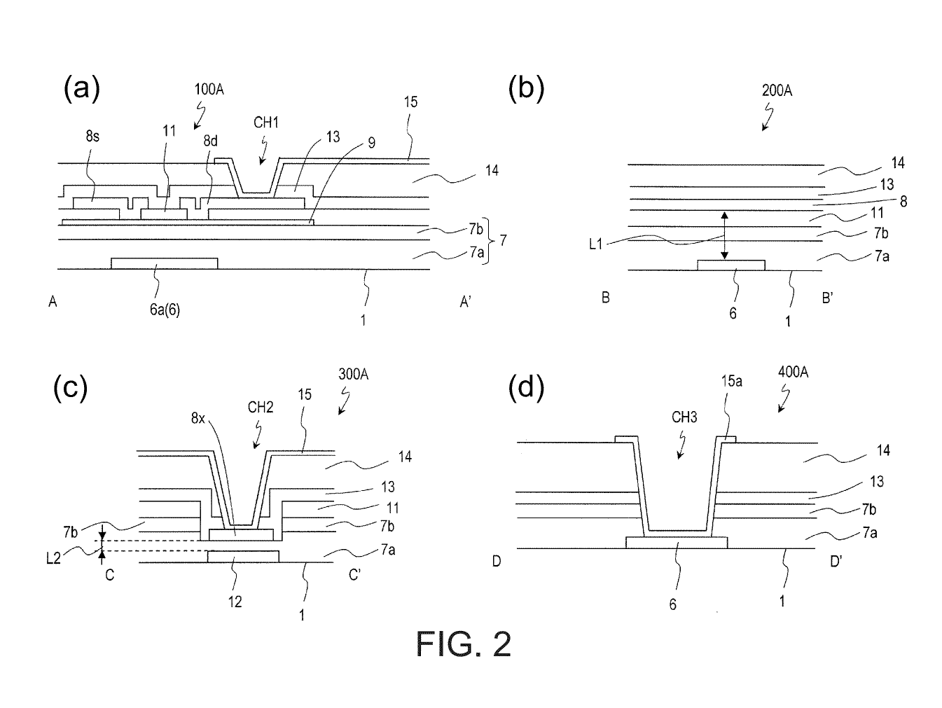

FIG. 1 schematically shows an example of a plan view structure of the semiconductor device (TFT substrate) 1000A in the present embodiment. FIG. 2(a) is a schematic cross-sectional view of a TFT 100A along the line A-A′ in FIG. 1. FIG. 2(b) is a schematic cross-sectional view of a gate/source intersection 200A along the line B-B′ in FIG. 1. FIG. 2(c) is a schematic cross-sectional view of an auxiliary capacitance unit 300A along the line C-C′ in FIG. 1. FIG. 2(d) is a schematic cross-sectional view of a gate terminal 400A along the line D-D′ in FIG. 1.

As shown in FIGS. 1 and 2 (a) to 2(d), the semiconductor devices 1000A has a substrate 1, a TFT 100A supported by the substrate 1, an auxiliary capacitance unit 300A, a gate wiring line 6, and a source wiring line 8. The TFT 100A has a gate electrode 6a formed of the same conductive film as the gate wiring line 6, a first insulating layer (gate insulating layer) 7 (7a and 7b) formed over the gate electrode 6a, an oxide semiconductor layer 9 formed over the first insulating layer 7, and a second insulating layer (etching stopper layer) 11 that is formed over the oxide semiconductor layer 9 and that comes into contact with a channel region of the oxide semiconductor layer 9, and a source electrode 8s and a drain electrode 8d that are electrically connected to the oxide semiconductor layer 9 and that are formed of the same conductive film. The auxiliary capacitance unit 300A has a first auxiliary capacitance electrode (first auxiliary capacitance wiring line) 12 formed of the same conductive film as the gate wiring line 6, a second auxiliary capacitance 8x formed of the same conductive film as the source wiring line 8, and the first insulating layer 7 (7a) that is positioned between the first auxiliary capacitance electrode 12 and the second auxiliary capacitance electrode 8x. When seen from a direction normal to the surface of the substrate 1, at the gate/source intersection 200A where the gate wiring line 6 and the source wiring line 8 overlap, the first insulating layer 7 (7a and 7b) and the second insulating layer 11 are formed between the gate wiring line 6 and the source wiring line 8, and a distance L2 between the first auxiliary capacitance electrode 12 and the second auxiliary capacitance electrode 8x (200 nm, for example) at the gate/source intersection 200A is shorter than a distance L1 between the gate wiring line 6 and the source wiring line 8 (550 nm, for example). Furthermore, it is preferable that the distance L2 between the first auxiliary capacitance electrode 12 and the second auxiliary capacitance electrode 8x be shorter than a distance between the gate electrode 6a and the oxide semiconductor layer 9 (450 nm, for example).

The semiconductor device 1000A with this type of structure has a sufficient auxiliary capacitance value even if the etching stopper layer 11 is formed, because the distance L2 between the first auxiliary capacitance electrode 12 and the second auxiliary capacitance electrode 8x is short (greater than or equal to 50 nm and less than or equal to 300 nm).

Furthermore, while details will be given later, the gate/source intersection 200A may have another insulating layer between the gate wiring line 6 and the source wiring line 8.

Next, the semiconductor device 1000A will be described in detail.

The semiconductor device 1000A of the present embodiment has an auxiliary capacitance unit 300A and a TFT 100A for each pixel. Furthermore, the semiconductor device 1000A has a gate/source intersection 200A where the gate wiring line 6 and the source wiring line 8 intersect, and a gate terminal 400A and a source terminal (not shown) located on a substantially outer edge of the substrate 1.

As shown in FIG. 1 and FIG. 2(a), a protective layer 13 and an interlayer insulating layer 14 are formed over the TFT 101, and a transparent pixel electrode 15 that is electrically connected to the drain electrode 8d in a contact hole CH1 formed in the protective layer 13 and the interlayer insulating layer 14 is formed. Furthermore, the source electrode 8s and the drain electrode 8d are in contact with the oxide semiconductor layer 9 in openings 11u in the etching stopper layer 11 formed over the oxide semiconductor layer 9.

As shown in FIG. 1 and FIG. 2(b), a lower gate insulating layer 7a and an upper gate insulating layer 7b are formed over the gate wiring line 6 at the gate/source intersection 200A, the etching stopper layer 11 is formed over the upper gate insulating layer 7b, the source wiring line 8 is formed over the etching stopper layer 11, the protective layer 13 is formed over the source wiring layer 8, and the interlayer insulating layer 14 is formed over the protective layer 13.

As shown in FIG. 1 and FIG. 2(c), the second auxiliary capacitance electrode 8x of the auxiliary capacitance unit 300A is formed in an opening 11v of the etching stopper layer 11 and the upper gate insulating layer 7b. Furthermore, a recessed portion is formed in a portion of the lower gate insulating layer 7a that overlaps the first auxiliary capacitance electrode 12, and a second auxiliary capacitance electrode 8x is formed in the recessed portion, for example. Furthermore, a protective layer 13 is formed over the etching stopper layer 11, and the interlayer insulating layer 14 is formed over the protective layer 13. A transparent pixel electrode 15 is electrically connected to the second auxiliary capacitance electrode 8x in the contact hole CH2 formed in the protective layer 13 and the interlayer insulating layer 14.

The gate terminal 400A has the gate wiring line 6, the lower and upper gate insulating layers 7a and 7b, and the transparent connection wiring line 15a that is electrically connected to the gate terminal 6 within the contact hole CH3 provided on the protective layer 13 and the interlayer insulating layer 14. The transparent connection wiring line 15a is formed of the same transparent conductive film as the transparent pixel electrode 15.

The gate electrode 6a is electrically connected to the gate wiring line 6. The gate wiring line 6, the gate electrode 6a, and the first auxiliary capacitance electrode 12 respectively have a multilayer structure with a W (tungsten) layer as an upper layer and a TaN (tantalum nitride) layer as a lower layer, for example. Alternatively, the gate wiring line 6, the gate electrode 6a, and the first auxiliary capacitance electrode 12 may respectively have a multilayer structure formed of Mo (molybdenum)/Al (aluminum)/ Mo, or may have a single layer structure, a two layer structure, or a multilayer structure with four or more layers. Furthermore, the gate wiring line 6, the gate electrode 6a, and the first auxiliary capacitance electrode 12 are respectively formed of an element selected from Cu (copper), Al, Cr (chromium), Ta (tantalum), Ti (titanium), Mo, and W, or an alloy or a metal nitride having these elements. The thickness of the gate wiring line 6, the gate electrode 6a, and the first auxiliary capacitance electrode 12 is respectively approximately 420 nm. It is preferable that the thickness of the gate wiring line 6, the gate electrode 6a, and the first auxiliary capacitance electrode 12 respectively be approximately 50 nm or more and 600 nm or less.

In the present embodiment, the gate insulating layer 7 has the lower gate insulating layer 7a and the upper gate insulating layer 7b. The gate insulating layer 7 may have a single layer structure or a multilayer structure with two or more layers. The lower gate insulating layer 7a is formed of a silicon nitride (SiNx), and the upper gate insulating layer is formed of an oxide nitride (SiOx), for example. The thickness of the lower gate insulating layer 7a is approximately 300 nm, and the thickness of the upper gate insulating layer 7b is approximately 50 nm, for example. As for the gate insulating layer 7, an oxide nitride (SiOx) layer, a silicon nitride (SiNx) layer, a silicon nitride oxide (SiOxNy; x>y) layer, a silicon oxide nitride (SiNxOy; x>y) layer, and the like may be used as appropriate. The insulating layers 7a and 7b are formed, respectively, by using the CVD (chemical vapor deposition) method.

An oxide semiconductor layer 9 includes In—Ga—Zn—O semiconductors (hereinafter, abbreviated as “IGZO semiconductors”), for example. Here, an In—Ga—Zn—O semiconductor is a ternary oxide including In (indium), Ga (gallium), and Zn (zinc), and there is no special limitation to the ratio (composition ratio) of In, Ga, and Zn, and In:Ga:Zn=2:2:1, In:Ga:Zn=1:1:1, and In:Ga:Zn=1:1:2 and the like are included, for example. The In—Ga—Zn—O semiconductor may be amorphous or crystalline. It is preferable that a crystalline In—Ga—Zn—O semiconductor have a c-axis with an orientation that is mostly vertical to the layer face. Such a crystalline structure of an In—Ga—Zn—O semiconductor is disclosed in Japanese Patent Application Laid-Open Publication No. 2012-134475, for example. All the content disclosed in Japanese Patent Application Laid-Open Publication No. 2012-134475 is incorporated by reference in the present specification.

A TFT having an In—Ga—Zn—O semiconductor has high mobility (more than 20 times that of a-Si TFT) and low leakage current (a hundredth of that of a-Si TFT), and therefore can be suitably used as a driver TFT and a pixel TFT.

The oxide semiconductor layer 9 is not limited to an In—Ga—Zn—O semiconductor layer. The oxide semiconductor layer may include Zn—O semiconductors (ZnO), In—Zn—O semiconductors (IZO (registered trademark)), Zn—Ti—O semiconductors (ZTO), Cd—Ge—O semiconductors, CdO (cadmium oxide) semiconductors, Mg—Zn—O semiconductors, In—Sn—Zn—O semiconductors (In₂O₃-5nO₂—ZnO, for example), In—Ga—Sn—O semiconductors, or the like. Also, it is possible to use, as the oxide semiconductor layer 9, amorphous ZnO, polycrystalline ZnO, or microcrystalline ZnO, which is a mixture of amorphous and polycrystalline, to which one or more types of impurity elements among group 1 elements, group 13 elements, group 14 elements, group 15 elements, and group 17 elements are added, or to which no impurity elements are added.

It is preferable that an amorphous oxide semiconductor layer be used as the oxide semiconductor layer 9. This is because an amorphous oxide semiconductor film can be manufactured at low temperature and can achieve a high mobility. The thickness of the oxide semiconductor layer 9 is approximately 50 nm, for example. It is preferable that the thickness of an oxide semiconductor layer 9 be greater than or equal to 30 nm and less than or equal to 100 nm.

The etching stopper layer 11 is formed so as to be in contact with the channel region of the oxide semiconductor layer 9. It is preferable that the etching stopper layer 11 be formed of an insulating oxide (SiO₂, for example). If the etching stopper layer 11 is formed of an insulating oxide, then deterioration of characteristics of semiconductors due to oxygen loss of the oxide semiconductor layer 9 can be prevented. In addition, the etching stopper layer 11 may be formed of a SiON (silicon nitride oxide, silicon oxide nitride), Al₂O₃, or Ta₂O₅, for example. The thickness of the etching stopper layer is approximately 150 nm, for example. It is preferable that the thickness of the etching stopper layer 11 be greater than or equal to 50 nm and less than or equal to 300 nm.

The source wiring line 8, the source electrode 8s, the drain electrode 8d, and the second auxiliary electrode 8x respectively have a multilayer structure of Ti/Al/Ti. Alternatively, the source wiring line 8, the source electrode 8s, the drain electrode 8d, and the second auxiliary capacitance electrode 12 may respectively have a multilayer structure formed of Mo (molybdenum)/Al (aluminum)/Mo, or may have a single layer structure, a two layer structure, or a multilayer structure with four or more layers. Also, the source wiring line 8, the source electrode 8s, the drain electrode 8d, and the second auxiliary electrode 8x may respectively be formed by an element chosen from among Al, Cr, Ta, Ti, Mo, and W, or an alloy or a metal nitride having these elements. The thickness of the source wiring line 8, the source electrode 8s, the drain electrode 8d and the second auxiliary capacitance electrode 8x, respectively, is approximately 350 nm, for example. The thickness of the source wiring line 8, the source electrode 8s, the drain electrode 8d and the second auxiliary capacitance electrode 8x, respectively, is approximately 50 nm or more or 600 nm or less, for example.

The protective layer 13 is made of SiNx, for example. The thickness of the protective layer 13 is approximately 200 nm, for example. It is preferable that the thickness of a protective layer 13 be greater than or equal to 100 nm and less than or equal to 500 nm.

The interlayer insulating layer 14 is formed of a photosensitive resin, for example. The thickness of the interlayer insulating layer 14 is approximately 2 μm, for example. It is preferable that the thickness of the interlayer insulating layer 14 be approximately 1 μm or more and 3 μm or less.

The transparent pixel electrode 15 and the transparent connection wiring line 15a are respectively formed of ITO (indium tin oxide). The thickness of the transparent pixel electrode 15 and the transparent connection wiring line 15a, respectively, is approximately 50 nm, for example. The thickness of the transparent pixel electrode 15 and the transparent connection wiring line 15a, respectively, is approximately 20 nm to 200 nm in thickness, for example.

The semiconductor device 1000A can be manufactured with the method explained below.

A method of manufacturing a display device 1000A provided with a TFT 100A and an auxiliary capacitance unit 300A, the method of manufacturing a display device including: (A) forming a gate electrode 6a and a first auxiliary capacitance electrode 12 of a same conductive film over a substrate 1; (B) forming a first insulating layer 7 (gate insulating layer) over the gate electrode 6a and the first auxiliary capacitance electrode 12; (C) forming an oxide semiconductor layer 9 over the first insulating layer 7 so as to overlap the gate electrode 6a when seen in a direction normal to the substrate 1; (D) forming a second insulating layer 11 having an opening 11v that overlaps the first auxiliary capacitance electrode 12 when seen from the direction normal to the substrate and an opening 11u that exposes a portion of the oxide semiconductor layer 9, by forming an insulating film over the oxide semiconductor layer 9 and the first insulating layer 7 and etching a portion of the first insulating layer 7 and the insulating film; and (E) forming a source electrode 8s, a drain electrode 8d, and a second auxiliary capacitance electrode 8x of the same conductive film, the second auxiliary capacitance electrode 8x being formed in the opening 11v, the step (E) including a step of electrically connecting the source electrode 8s and the drain electrode 8d to the oxide semiconductor layer 9 in the opening 11u.

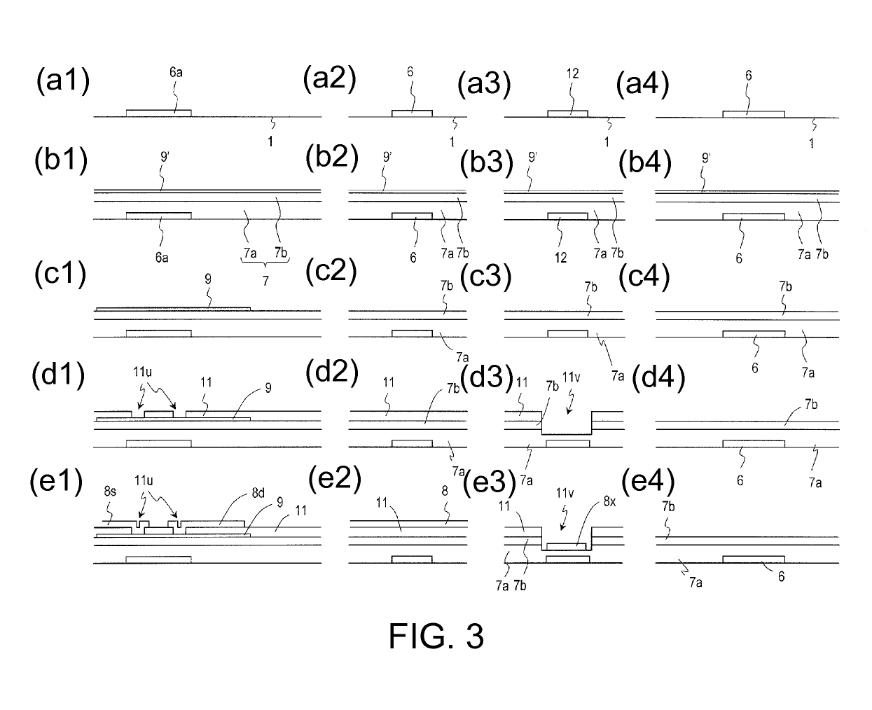

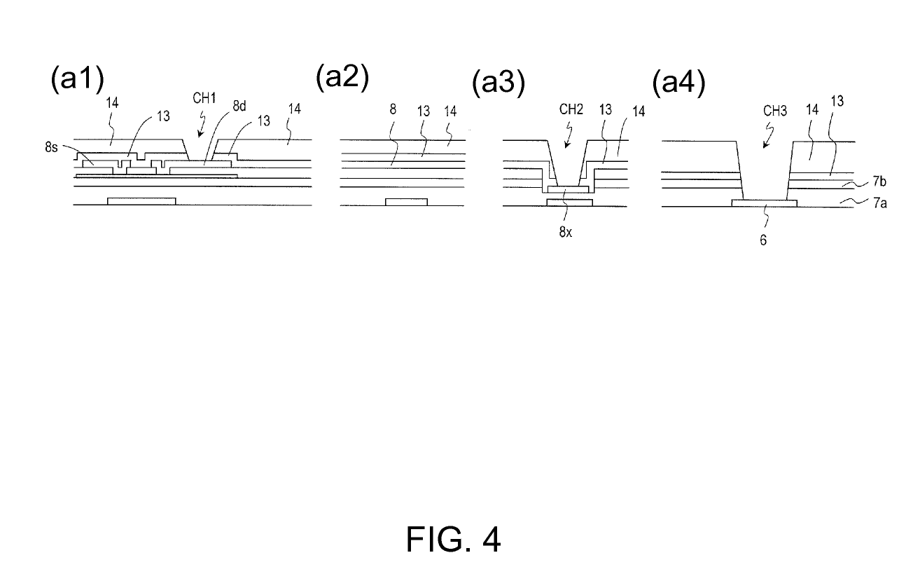

Next, an example of a method of manufacturing the semiconductor device 1000A will be described with reference to FIGS. 3 and 4. FIGS. 3 (a2) to 3(e1) and 4(a1) are cross-sectional views describing a manufacturing method of the TFT 100A that corresponds to FIG. 2(a). FIGS. 3 (a2) to 3(e2) and 4(a2) are cross-sectional views describing a forming method of the gate/source intersection 200A that corresponds to FIG. 2(b). FIGS. 3(a3) to 3(e3) and 4(a3) are cross-sectional views describing a method of forming the auxiliary capacitance unit 300A that corresponds to FIG. 2(c). FIGS. 3(a4) to 3(e4) and 4(a4) are cross-sectional views describing a method of forming the gate terminal 400A that corresponds to FIG. 2(d).

First, a metal film for a gate wiring line that is not shown (with a thickness between approximately 50 nm and 600 nm inclusive, for example) is formed on the substrate 1. The metal film for a gate wiring line is formed on the substrate 1 using methods such as sputtering.

Then, as shown in FIGS. 3(al) to 3(a4), the gate wiring line 6 and the first auxiliary wiring line (first auxiliary capacitance electrode) 12 are formed by patterning. At this point, as shown in FIG. 3(a1), in the region forming the TFT 100A, a gate electrode 6a to be electrically connected to the gate wiring line 6 is formed. A portion of the gate wiring line 6 becomes the gate electrode 6a, in this example.

Next, as shown in FIGS. 3(b1) to 3(b4), the gate insulating layer 7 having the lower gate insulating layer (approximately 300 nm in thickness, for example) 7a and the upper gate insulating layer (approximately 50 nm in thickness, for example) 7b, are formed on the gate wiring line 6, the gate electrode 6a, and the first auxiliary capacitance wiring line 12.

Then, the oxide semiconductor film (approximately 50 nm in thickness) 9′is formed on the upper gate insulating layer 7b by sputtering.

Then, as shown in FIGS. 3(c1) to 3(c4), the oxide semiconductor film 9′ is patterned using a known method. As a result, as shown in FIG. 3(c1), an island-shaped oxide semiconductor layer 9 is formed, and the oxide semiconductor layer 9 is not formed in the regions shown in FIGS. 3(c2) to 3(c4).

Next, as shown in FIGS. 3(d1) to 3(d4), an etching stopper film (with thickness approximately 150 nm), which is not shown, is formed by the CVD method and the like over the upper gate insulating layer 7b and the oxide semiconductor layer 9, and is patterned using a known method. As a result, as shown in FIG. 3(d1), the etching stopper layer 11 is formed so as to cover the area of the oxide semiconductor layer 9 to be the channel region. In the etching stopper layer 11, openings 1 lu that electrically connect the source electrode 8s and the drain electrode 8d to the oxide semiconductor layer 9 to be mentioned later are formed. Furthermore, as shown in FIG. 3(d3), in the region where the auxiliary capacitance unit 300A is formed, the recessed portion 11v is formed by simultaneously etching the etching stopper film, the upper gate insulating layer 7b, and the lower gate insulating layer 7a. The etching stopper layer 11 and the upper gate insulating layer 7b have an opening that overlaps the recessed portion 11v. In the region shown in FIG. 3 (d1), the oxide semiconductor layer 9 formed under the etching stopper film functions as an etching stopper, and thus, the upper gate insulating layer 7b and the lower gate insulating layer 7a under the oxide semiconductor layer 9 are not etched. In the region shown in FIG. 3(d2), the etching stopper layer 11 is formed on the upper gate insulating layer 7b, and no etching stopper layer 11 is formed in the region shown in FIG. 3(d4).

Then, as shown in FIGS. 3(e1) to 3(e4), the source wiring line 8, the source electrode 8s, the drain electrode 8d, and the second auxiliary capacitance electrode 8x (with thickness approximately 350 nm, respectively, for example) are formed using a known method. The source wiring line 8, the source electrode 8s, and the drain electrode 8d are electrically connected to each other. As shown in FIG. 3(e1), the source electrode 8s and the drain electrode 8d are formed over the etching stopper layer 11, and are electrically connected to the oxide semiconductor layer 9 in the openings 11u of the etching stopper layer 11. In the regions shown in FIG. 3(e2), the source wiring line 8 is formed over the etching stopper layer 11. In the region shown in FIG. 2(e3), a second auxiliary capacitance electrode 8x and an auxiliary capacitance electrode 300A are formed in the recessed portion 11v.

Next, as shown in FIGS. 4(a1) to 4(a4), the protective layer (with approximately 150 nm thickness, for example) 13 is formed over the source electrode 8s and the drain electrode 8d, and the interlayer insulating layer (with approximately 1 μm thickness, for example) 14 is formed over the protective layer 13 by photolithography.

In the region shown in FIG. 4(a1), the contact hole CH1 that electrically connects the transparent pixel electrode 15 mentioned later to the drain electrode 8d is formed in the protective layer 13 and the interlayer insulating layer 14. Furthermore, in the region shown in FIG. 4(a3), a contact hole CH2 that electrically connects the transparent pixel electrode 15 mentioned later and the auxiliary capacitance electrode 8x is formed in the protective layer 13 and the interlayer insulating layer 14. Furthermore, in the region shown in FIG. 4(a4), a contact hole CH3 that electrically connects the transparent connection wiring line 15a mentioned later to the gate wiring line 6 is formed in the lower gate insulating layer 7a, the upper gate insulating layer 7b, the protective layer 13, and the interlayer insulating layer 14. In the region shown in FIG. 4(a2), the source wiring line 8 is formed over the protective layer 13, and the interlayer insulating layer 14 is formed over the protective layer 13.

Then, as shown in FIGS. 1(a) to 1(d), the transparent pixel electrode 15 and the transparent connection wiring line 15a (with approximately 150 nm thickness, respectively, for example) are formed over the interlayer insulating layer 14 with a known method. As shown in FIG. 1(a), the transparent pixel electrode 15 and the drain electrode 8d are electrically connected within the contact hole CH1. As shown in FIG. 1(c), the transparent pixel electrode 15 and the second auxiliary capacitance electrode 8x are electrically connected in the contact hole CH2. As shown in FIG. 1(d), the transparent connection wiring line 15a and the gate wiring line 6 are electrically connected in the contact hole CH3.

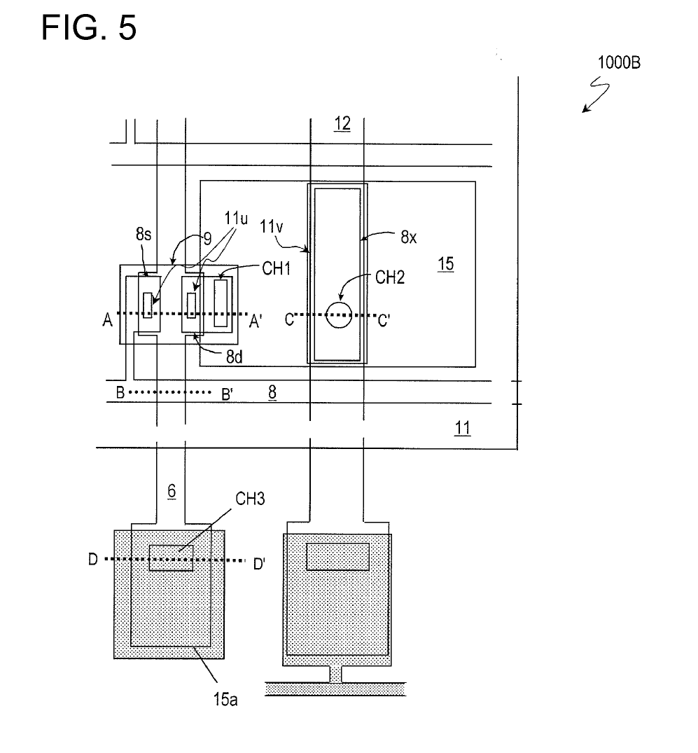

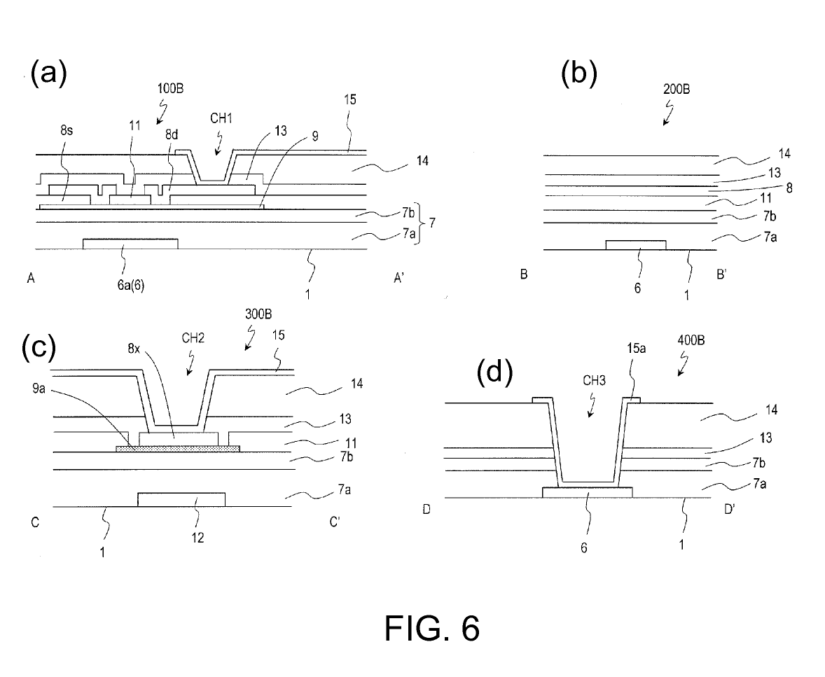

Next, a semiconductor device 100B of another embodiment according to the present invention will be explained with reference to FIGS. 5 and 6. Constituting elements that are shared with the semiconductor device 1000A will be assigned the same reference characters, and duplicate explanations will be omitted.

FIG. 5 schematically shows an example of a plan view structure of the semiconductor device (TFT substrate) 1000B in the present embodiment. FIG. 6(a) is a schematic cross-sectional view of a TFT 100B along the line A-A′ in FIG. 5. FIG. 6(b) is a schematic cross-sectional view of a gate/source intersection 200B along the line B-B′ in FIG. 5. FIG. 6(c) is a schematic cross-sectional view of an auxiliary capacitance unit 300B along the line C-C′ in FIG. 5. FIG. 6(d) is a schematic cross-sectional view of a gate terminal 400B along the line D-D′ in FIG. 5.

As shown in FIGS. 5 and 6, the configuration of the auxiliary capacitance unit 300B for the semiconductor device 1000B is different from that of the semiconductor device 1000A. Specifically, the auxiliary capacitance unit 300B of the semiconductor device 1000B includes the first auxiliary capacitance electrode 12 formed over the substrate 1, the lower gate insulating layer 7a formed over the first auxiliary capacitance electrode 12, the upper gate insulating layer 7b formed over the lower gate insulating layer 7a, the oxide semiconductor layer 9a formed over the lower gate insulating layer 7b, and the second auxiliary capacitance electrode 8x that is in contact with the oxide semiconductor layer 9a. The second auxiliary capacitance electrode 8x is formed in the opening 11v of the etching stopper layer 11. The protective layer 13 is formed over the etching stopper layer 11, and the interlayer insulating layer 14 is formed over the protective layer 13. The contact hole CH2 is provided in the protective layer 13 and the interlayer insulating layer 14, and the second auxiliary capacitance electrode 8x and the transparent pixel electrode 15 are electrically connected in the contact hole CH2.

Next, a method of manufacturing the semiconductor device 1000B will be described.

A method of manufacturing a semiconductor device provided with the TFT 100B and the auxiliary capacitance unit 300B, including: (A) forming a gate electrode 6a and a first auxiliary capacitance electrode 12 of a same conductive film, over a substrate 1; (B) forming a first insulating layer 7 over the gate electrode 6a and the first auxiliary capacitance electrode 12; (C) forming an oxide semiconductor layer 9 and an oxide layer 9a of a same oxide film, the oxide semiconductor layer 9 being formed over the first insulating layer 7 so as to overlap the gate electrode 6a when seen in a direction normal to the substrate 2, the oxide layer 9a being formed over the first insulating layer 7 so as to overlap the first auxiliary capacitance electrode 12 when seen in the direction normal to the substrate 2; (D) forming a second insulating layer 11 having an opening 11v that exposes the oxide layer 9a and an opening 11u that exposes a portion of the oxide semiconductor layer 9; and (E) forming a source electrode 8s, a drain electrode 8d, and a second auxiliary capacitance electrode 8x of a same conductive film, the second auxiliary capacitance electrode 8x being formed over the oxide layer 9a in the opening 11v, the step (E) including a step of electrically connecting the source electrode 8s and the drain electrode 8d to the oxide semiconductor layer 9 in the opening 11u.

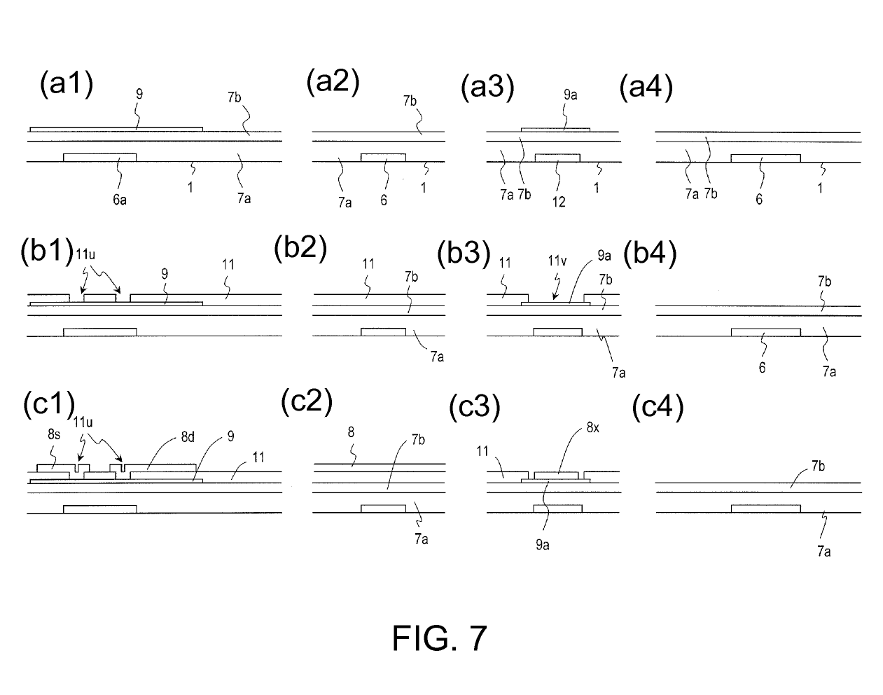

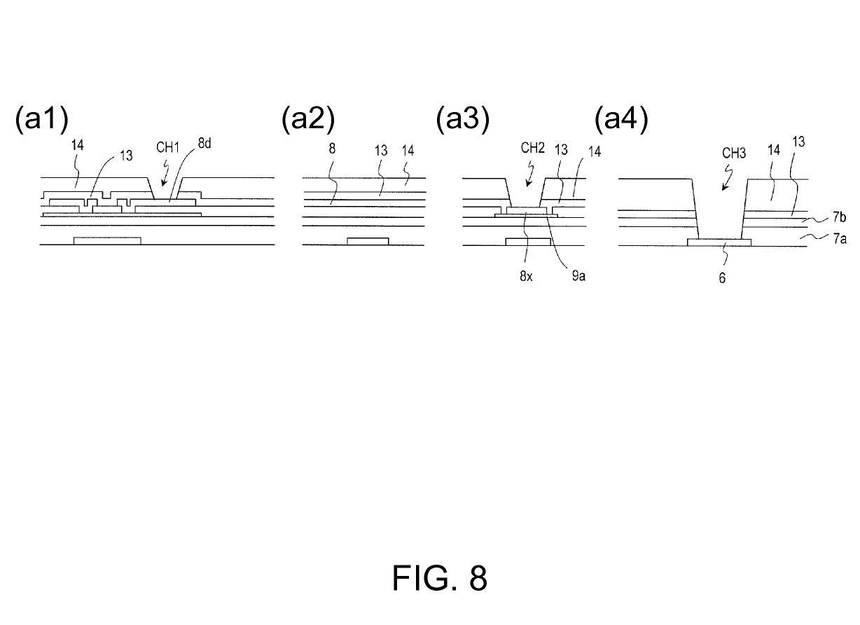

Next, an example of a method of manufacturing the semiconductor device 1000B will be described with reference to FIGS. 7 and 8. FIGS. 7 (a1) to 7(c1) and FIG. 8(al) are cross-sectional views describing a method of manufacturing the TFT 100B that corresponds to FIG. 6(a). FIGS. 7(a2) to 7(c2) and FIG. 8(a2) are cross-sectional views describing a method of forming the gate/source intersection 200B that corresponds to FIG. 6(b). FIGS. 7(a3) to 7(c3) and 8(a3) are cross-sectional views describing a method of forming the auxiliary capacitance unit 300B that corresponds to FIG. 6(c). FIGS. 7(a4) to 7(c4), and 8(a4) are cross-sectional views describing a method of forming the gate terminal 400B that corresponds to FIG. 6(d).

As mentioned above, the gate electrode 6a, the gate wiring line 6, the first auxiliary capacitance electrode 12, and the lower and upper gate electrodes 7a and 7b are formed over the substrate 1.

Next, the oxide semiconductor film is formed over the upper gate insulating layer 7b by sputtering.

Then, as shown in FIGS. 7(a1) to 7(a4), the oxide semiconductor film is patterned using a known method. As a result, as shown in FIGS. 7(a1) to 7(a3), in the regions where the TFT 100B and the auxiliary capacitance unit 300B are formed, the island-shaped oxide semiconductor layers 9 and 9a are respectively formed, and the oxide semiconductor layer 9 is not formed in the regions shown in FIGS. 3(a2) and 3(a4).

Next, as shown in FIGS. 7(b1) to 7(b4), an etching stopper film (not shown) is formed by the CVD method and the like over the upper gate insulating layer 7b and the oxide semiconductor layer 9, and is patterned by a known method. As a result, as shown in FIG. 7(b1), the etching stopper layer 11 is formed so as to cover the region to be the channel region of the oxide semiconductor layer 9. In the etching stopper layer 11, the openings 11u that electrically connect the source electrode 8s and the drain electrode 8d to the oxide semiconductor layer 9 mentioned later are formed. Furthermore, as shown in FIG. 7(b3), in the regions formed in the auxiliary capacitance unit 300B, the etching stopper layer 11 has the opening 11v formed therein, exposing the oxide semiconductor layer 9a. In the region shown in FIG. 7(b2), the etching stopper layer 11 is formed on the upper gate insulating layer 7b, and no etching stopper layer 11 is formed in the region shown in FIG. 7(b4).

Next, as shown in FIGS. 7(c1) to 7(c4), the source wiring line 8, the source electrode 8s, the drain electrode 8d, and the second auxiliary capacitance electrode 8x are formed by a known method. The source wiring line 8, the source electrode 8s, and the drain electrode 8d are electrically connected. As shown in FIG. 7(c1), the source electrode 8s and the drain electrode 8d are formed over the etching stopper layer 11, and are electrically connected to the oxide semiconductor layer 9 in the opening 11u of the etching stopper layer 11. In the regions shown in FIG. 7(c2), the source wiring line 8 is formed over the etching stopper layer 11. In a region shown in FIG. 7(c3), the second auxiliary capacitance electrode 8x that is in contact with the oxide semiconductor layer 9a and the auxiliary capacitance electrode 300B are formed within the opening 11v.

Then, as shown in FIGS. 8(a1) to 8(a4), by the CVD method, for example, the protective layer 13 is formed over the source electrode 8s and the drain electrode 8d, and the interlayer insulating layer 14 is formed over the protective layer 13 by photolithography.

In a region shown in FIG. 8(a1), the contact hole CH1 that electrically connects the transparent pixel electrode 15 mentioned later to the drain electrode 8d is formed in the protective layer 13 and the interlayer insulating layer 14. Furthermore, in a region shown in FIG. 8(a3), the contact hole CH2 that electrically connects the transparent pixel electrode 15 mentioned later and the auxiliary capacitance electrode 8x is formed in the protective layer 13 and the interlayer insulating layer 14. Furthermore, in the region shown in FIG. 8(a4), the contact hole CH3 that electrically connects the transparent connection wiring line 15a mentioned later and the gate wiring line 6 is formed in the lower gate insulating layer 7a, the upper gate insulating layer 7b, the protective layer 13, and the interlayer insulating layer 14. In the region shown in FIG. 8(a2), the source wiring line 8 is formed over the protective layer 13, and the interlayer insulating layer 14 is formed over the protective layer 13.

Then, as shown in FIGS. 6(a) to 6(d), the transparent pixel electrode 15 and the transparent connection wiring line 15a are formed over the interlayer insulating layer 14 with a known method. As shown in FIG. 6(a), the transparent pixel electrode 15 and the drain electrode 8d are electrically connected in the contact hole CH1. As shown in FIG. 6(c), the transparent pixel electrode 15 and the second auxiliary capacitance electrode 8x are electrically connected in the contact hole CH2. As shown in FIG. 6(d), the transparent connection wiring line 15a and the gate wiring line 6 are electrically connected in the contact hole CH3.

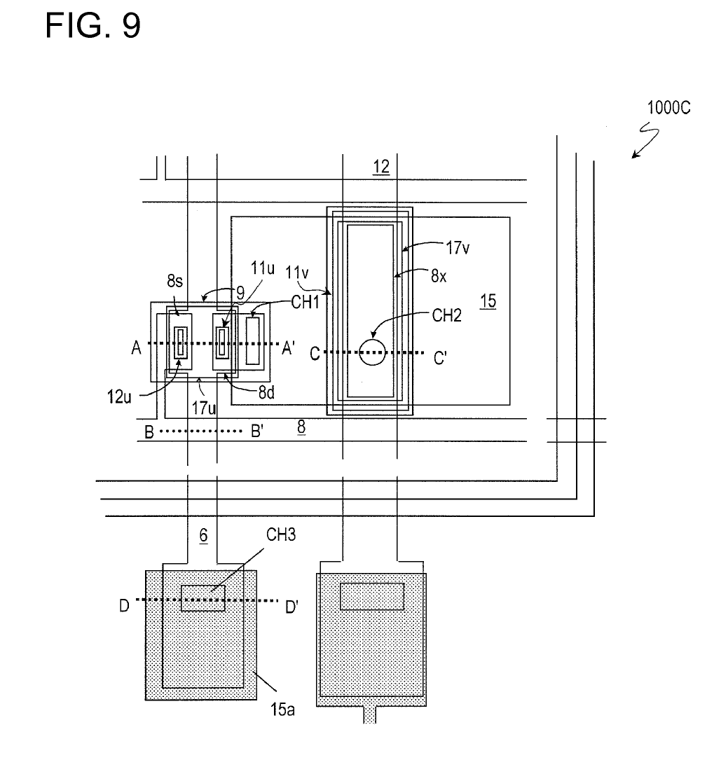

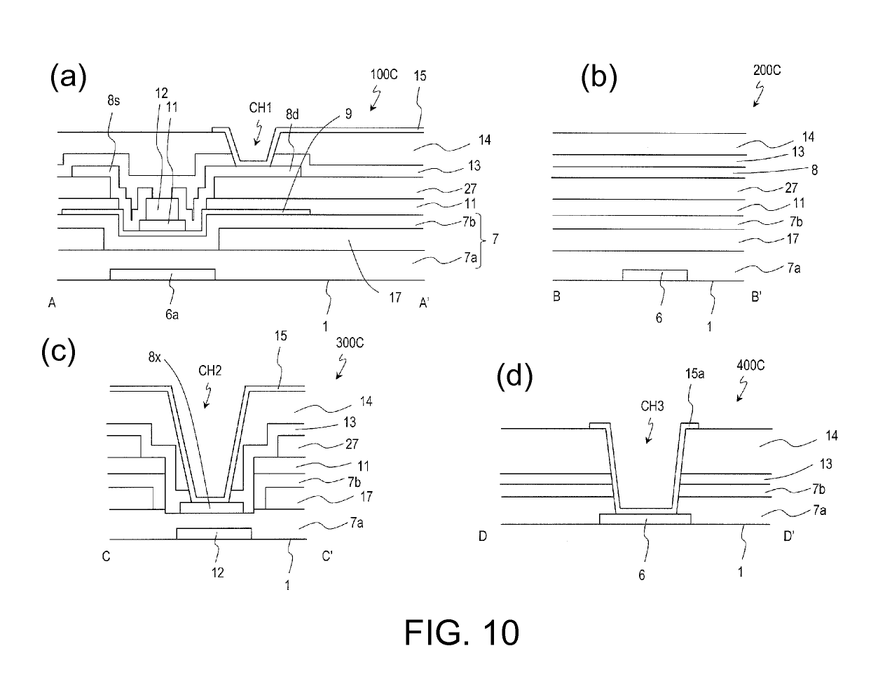

Next, the semiconductor device 1000C of yet another embodiment of the present invention will be described with reference to FIGS. 9 and 10. Constituting elements that are shared with the semiconductor device 1000A will be assigned the same reference characters, and duplicate explanations will be omitted.

FIG. 9 schematically shows an example of a plan view structure of the semiconductor device (TFT substrate) 1000C in the present embodiment. FIG. 10(a) is a schematic cross-sectional view of a TFT 100C along the line A-A′ in FIG. 9. FIG. 10(b) is a schematic cross-sectional view of a gate/source intersection 200C along the line B-B′ in FIG. 9. FIG. 10(c) is a schematic cross-sectional view of a TFT 300C along the line C-C′ in FIG. 9. FIG. 10(d) is a schematic cross-sectional view of a gate terminal 400C along the line D-D′ in FIG. 9.

The semiconductor device 100C is different from the semiconductor device 1000A in that a third insulating layer (first SOG (spin on glass) insulating layer) 17 is formed between the lower gate insulating layer 7a and the upper gate insulating layer 7c, and in that a fourth insulating layer (second SOG insulating layer) 27 is formed between the etching stopper layer 11, and the source electrode 8s, the drain electrode 8d, and the source wiring line 8.

In the gate/source intersection 200C of the semiconductor device 1000C, the first and second SOG insulating layers 17 and 27 are formed between the gate wiring line 6 and the source wiring line 8. As a result, because the length (approximately 4.4 μm, for example) between the gate wiring line 6 and the source wiring line 8 is greater than the length (approximately 250 nm, for example) between the gate wiring line 6 and the source wiring line 8 of the gate/source intersection 200A, the effect of preventing the gate wiring line 6 and the source wiring line 8 from short-circuiting is achieved to a greater degree. Furthermore, the channel portion can shorten the distance between the gate electrode 6a and the oxide semiconductor layer 9, and thus, the ON current of the TFT characteristics can be large.

The first and second SOG layers are formed of a photosensitive SOG material. The thickness of the first and second SOG layers is approximately 2 μm, respectively. It is preferable that the respective thickness of the first and second SOG layers be between approximately 0.5 μm and approximately 3.5 μm inclusive.

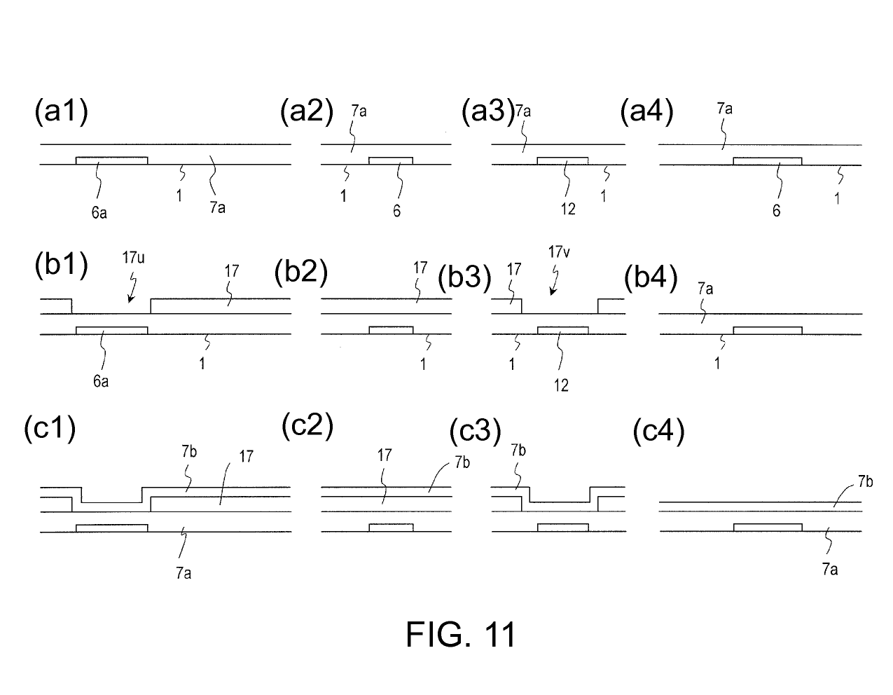

Next, an example of a method of manufacturing the semiconductor device 1000C will be described with reference to FIGS. 11 to 13. FIGS. 11(a1) to 11(c1), 12(a2) to 12(d1), 13(a1), and 13(b1) are cross-sectional views describing the manufacturing method of a TFT 100C that corresponds with FIG. 10(a). FIGS. 11(a2) to 11(c2), 12(a2) to 12(d2), 13(a2), and 13(b2) are cross-sectional views describing a forming method of the gate/source intersection 200C that corresponds with FIG. 10(b). FIGS. 11(a3) to 11(c3), 12(a3) to 12(d3), 13(a3), and 13(b3) are cross-sectional views describing a method of forming the gate/source intersection 300C that corresponds with FIG. 10(c). FIGS. 11(a4) to 11(c4), 12(a4) to 12(d4), 13(a4), and 13(b4) are cross-sectional views describing a method of forming the gate terminal 300C that corresponds with FIG. 10(d).

First, the metal film for a gate wiring line (not shown) is formed over the substrate 1. The metal film for a gate wiring line is formed on the substrate 1 by methods such as sputtering.

Next, as shown in FIGS. 11(a1) to 11(a4), the gate electrode 6a, the gate wiring line 6, and the first auxiliary capacitance wiring line (first auxiliary capacitance electrode) 12 are formed by patterning the metal film for the gate wiring line. During this time, as shown in FIG. 11(a1), the gate electrode 6a that is electrically connected to the gate wiring line 6 has a gate electrode 6a formed in the region that forms the TFT 100C. A portion of the gate wiring line 6 becomes the gate electrode 6a, in this example.

Next, the lower gate insulating layer 7a is formed over the gate wiring line 6, the gate electrode 6a, and the first auxiliary capacitance wiring line 12 by the CVD method and the like.

Next, as shown in FIGS. 11(b1) to 11 (b4), the first SOG insulating layer (approximately 2.0 μm in thickness) 17 is formed by the spin coating method and the photography method, for example. At this time, as shown in FIG. 11 (b1), the first SOG insulating layer 17 has an opening 17u that overlaps the gate electrode 6a when seen from a direction normal to the substrate 1. Furthermore, as shown in FIG. 11 (b3), the first SOG insulating layer 17 has an opening 17v that overlaps the first auxiliary capacitance wiring line 12 when seen from a direction normal to the substrate 1. The first SOG insulating layer 17 is not formed in the region shown in FIG. 11(b4).

Next, as shown in FIGS. 11(c1) to 11(c3), the upper gate insulating layer 7b is formed over the first SOG insulating layer 17 by the CVD method or the like. The upper gate insulating layer 7b is formed over the lower gate insulating layer 7a in the region shown in FIG. 11(c4).

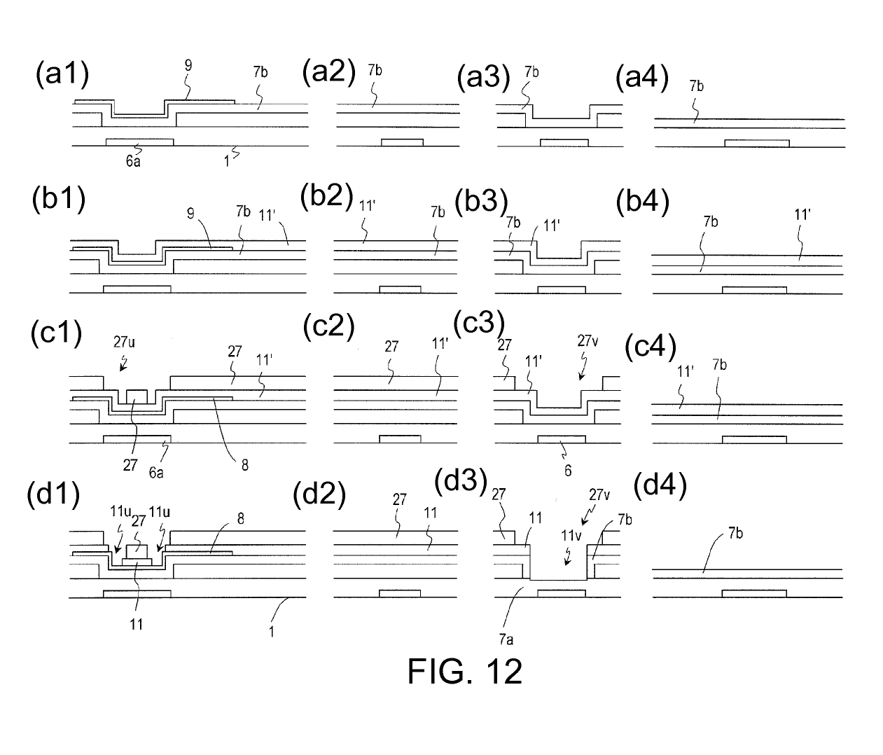

Next, the oxide semiconductor film is formed over the upper gate insulating layer 7b by sputtering. Then, the oxide semiconductor layer is patterned by a known method, and as shown in FIG. 12(a1), the oxide semiconductor film 9 is formed so as to overlap the gate electrode 6a when seen from a direction normal to the substrate 1. The oxide semiconductor layer 9 is not formed in the region shown in FIGS. 12(a2) to 12(a4).

Then, as shown in FIGS. 12(b1) to 12(b4), an etching stopper film 11′ is formed over the upper gate insulating layer and the oxide semiconductor layer 9 by the CVD method or the like.

Next, as shown in FIGS. 12(c1) to 12(c4), the second SOG insulating layer 27 is formed by the spin coating method, photolithography, and the like. As shown in FIG. 12(c1), the second SOG insulating layer 27 has an opening 27u that overlaps the gate electrode 6a when seen from a direction normal to the substrate 1. Within the opening 27u, the island-shaped second SOG insulating layer 27 is formed, and the second SOG insulating layer 27 overlaps the channel region of the oxide semiconductor layer 9 when the island-shaped second SOG insulating layer 27 is seen from a direction normal to the substrate. Furthermore, as shown in FIG. 12(c3), the second SOG insulating layer 27 has an opening 27v formed therein that overlaps the first auxiliary capacitance electrode 12 when seen from a direction normal to the substrate 1.

Next, as shown in FIGS. 12(d1) to 12(d4), the etching stopper film 11′ and the upper gate insulating layer 7b are patterned by a known method. As a result, as shown in FIG. 12(d1), when seen in a direction normal to the substrate 1, an island-shaped etching stopper layer 11 that overlaps the channel region of the oxide semiconductor layer 9 is formed. In both sides of the etching stopper layer 11, an opening 11u that electrically connects the source electrode 8s and the drain electrode 8d to the oxide semiconductor layer 9 mentioned later is formed. Furthermore, in a region shown in FIG. 12(d3), a portion of the etching stopper film 11′ (refer to FIG. 11(c3)) and the upper gate insulating layer 7b are etched simultaneously, and the opening 27v of the second SOG insulating layer 27 is formed in the recessed portion 11v located within the opening 27. At this time, a portion of the lower gate insulating layer 27a is sometimes etched. Furthermore, in a region shown in FIG. 12(d4), a portion of the etching stopper film 11′ (refer to FIG. 11(c4)) is removed by etching, thereby exposing the upper gate insulating layer 7b. In the region shown in FIG. 12(d2), the etching stopper layer 11 is formed below the second SOG insulating layer 27.

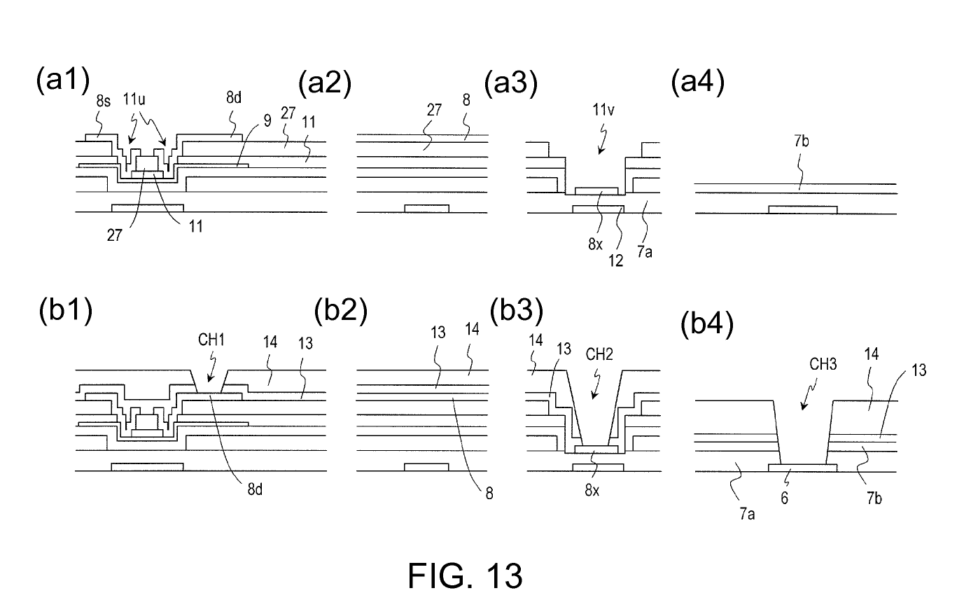

Then, as shown in FIGS. 13(a1) to 13(a4), the source wiring line 8, the source electrode 8s, the drain electrode 8d, and the second auxiliary capacitance electrode 8x are formed by a known method. As shown in FIG. 13(a1), the source electrode 8s and the drain electrode 8d are respectively in contact with the oxide semiconductor layer 9. As shown in FIG. 13(a2), the source wiring line 8 is formed over the second SOG insulating layer 27. As shown in FIG. 13(a3), the second auxiliary capacitance electrode 8x is formed within the recessed portion 11v. The second auxiliary capacitance electrode 8x overlaps the first auxiliary capacitance electrode 12 across the lower gate insulating layer 7a.

Then, as shown in FIGS. 13(b1) to 13(b3), a protective film (not shown) is formed over the source wiring line 8, the source electrode 8s, the drain electrode 8d, and the second auxiliary capacitance electrode 8x by the CVD method or the like. Furthermore, in the region shown in FIG. 13(b4), a protective film is formed over the upper gate insulating layer 7b. Next, the interlayer insulating layer 14 is formed over the protective film by the photolithography method. The protective film is patterned using the interlayer insulating layer 14 as a mask. As a result, as shown in FIG. 13(b1), the contact hole CH1 is formed in the protective layer 13 and the interlayer insulating layer 14, and is formed over the drain electrode 8d, thus exposing a portion of the surface of the drain electrode 8d. Furthermore, as shown in FIG. 13(b3), the contact hole CH2 that exposes the surface of the second auxiliary capacitance electrode 8x is formed in the protective layer 13 and the interlayer insulating layer 14. Furthermore, in the region shown in FIG. 13(b4), the protective film, the lower gate insulating layer 7a, and the upper gate insulating layer 7b are simultaneously etched, and the contact hole CH3 is formed in the protective layer 13 and the interlayer insulating layer 14. By forming the contact hole CH3, a portion of the gate wiring line 6 is exposed.

Then, as shown in FIGS. 10(a) to 10(d), the transparent pixel electrode 15 and the transparent connection wiring line 15a are formed over the interlayer insulating layer 14 by a known method. As shown in FIG. 10(a), the transparent pixel electrode 15 and the drain electrode 8d are electrically connected in the contact hole CH1. As shown in FIG. 10(c), the transparent pixel electrode 15 and the second auxiliary capacitance electrode 8x are electrically connected in the contact hole CH2. As shown in FIG. 10(d), the transparent connection wiring line 15a and the gate wiring line 6 are electrically connected in the contact hole CH3. The transparent pixel electrode 15 is not formed over the interlayer insulating layer 14 shown in a region in FIG. 10(b).

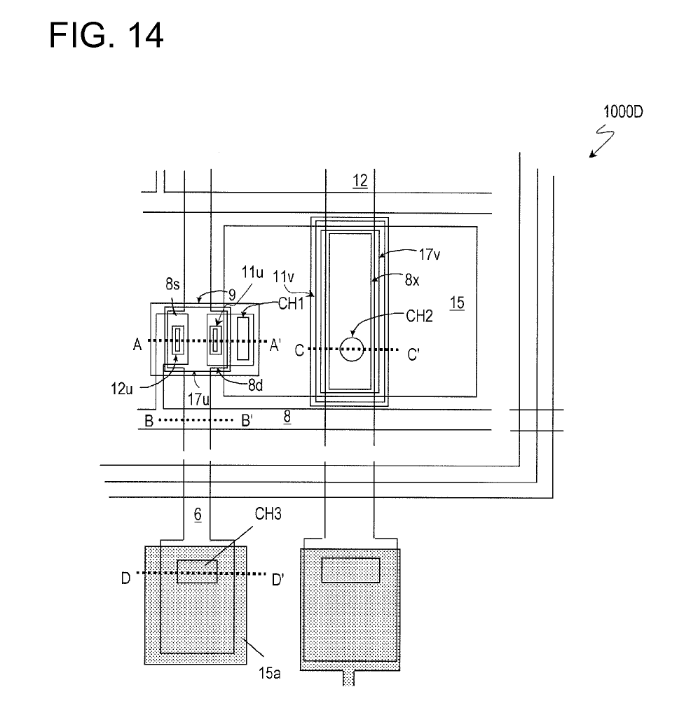

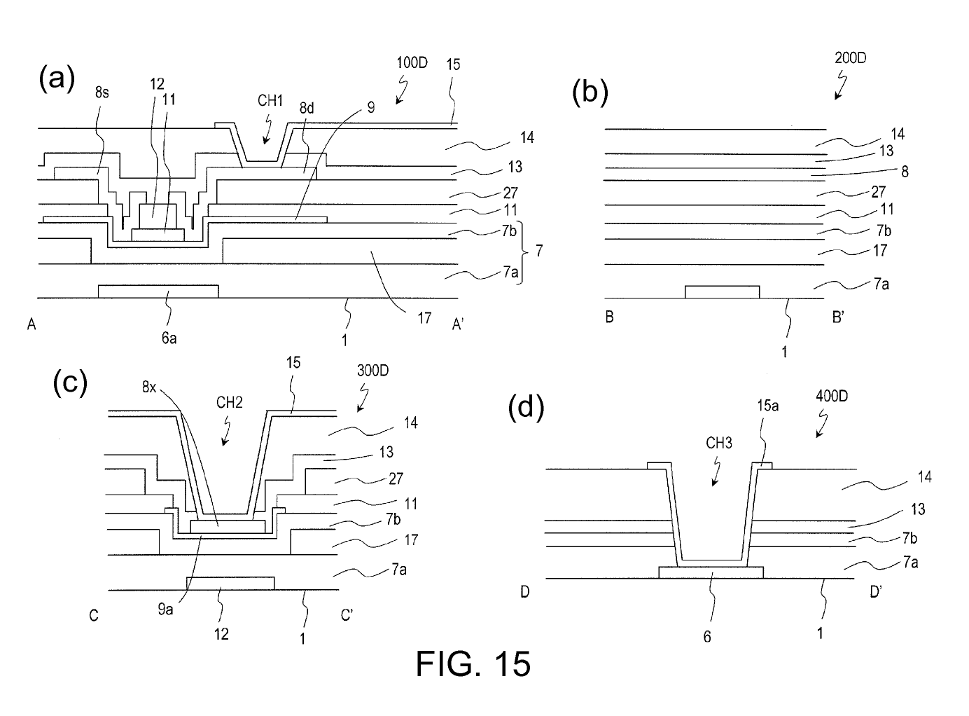

Next, the semiconductor device 1000D of yet another embodiment of the present invention will be described with reference to FIGS. 14 and 15. Constituting elements that are shared with the semiconductor device 1000A will be assigned the same reference characters, and duplicate explanations will be avoided.

FIG. 14 schematically shows an example of a plan view structure of the semiconductor device (TFT substrate) 1000D in the present embodiment. FIG. 15(a) is a schematic cross-sectional view of a TFT 100D along the line A-A′ in FIG. 14. FIG. 15(b) is a schematic cross-sectional view of a gate/source intersection 200B along the line B-B′ in FIG. 14. FIG. 15(c) is a schematic cross-sectional view of an auxiliary capacitance unit 300D along the line C-C′ in FIG. 14. FIG. 15(d) is a schematic cross-sectional view of a gate terminal 400D along the line D-D′ in FIG. 14.

The semiconductor device 1000D differs from the semiconductor device 1000C in that the oxide semiconductor layer 9a is formed below the second auxiliary capacitance electrode 8x.

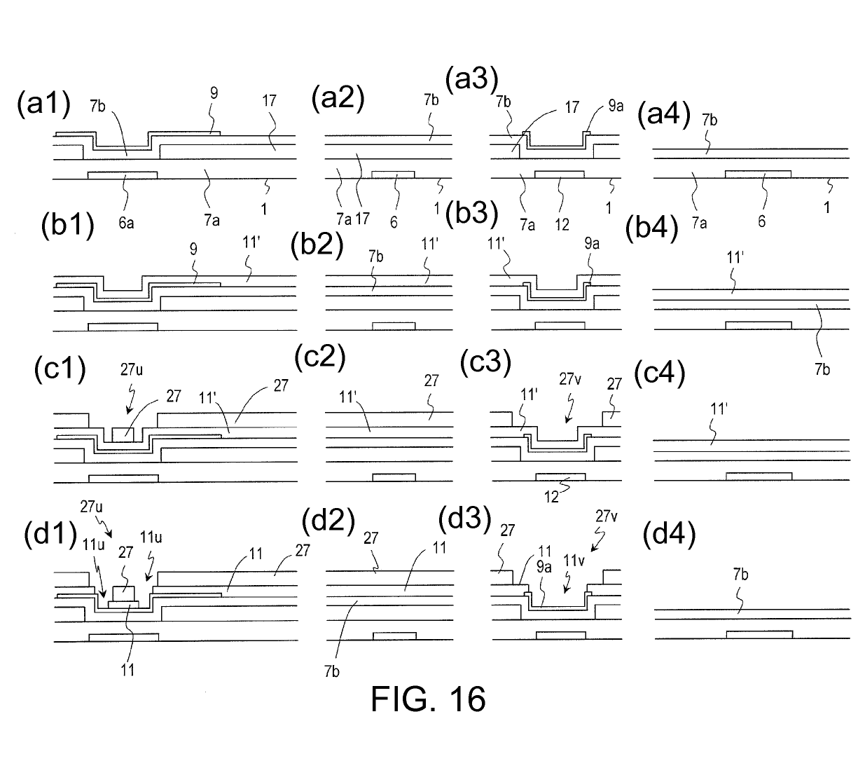

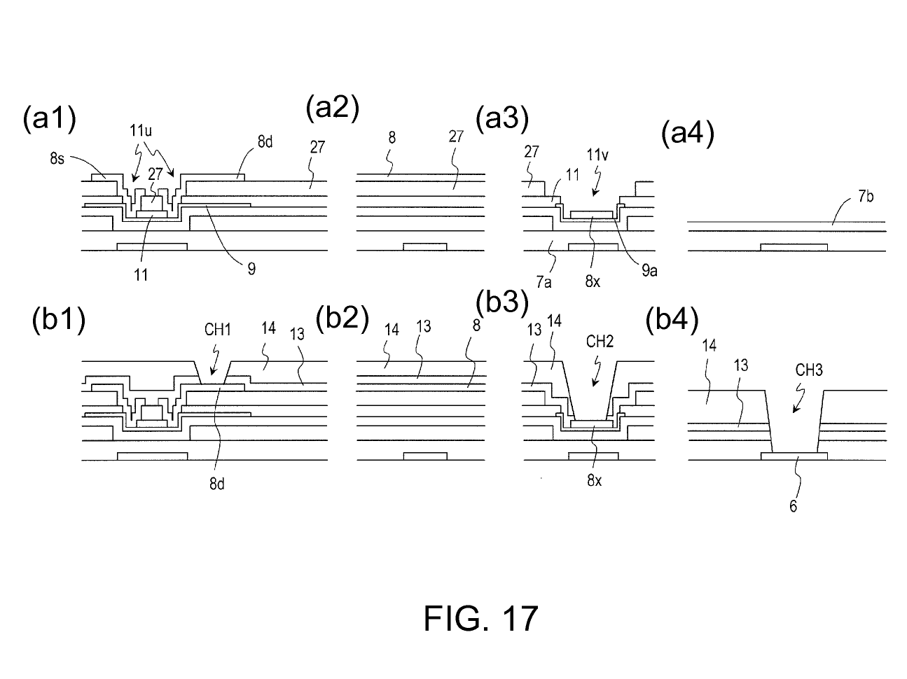

Next, an example of a method of manufacturing the semiconductor device 1000D will be described with reference to FIGS. 16 to 17. FIG. 16(a1) to FIG. 16(d1), FIG. 17(a1), and FIG. 17(b1) are cross-sectional views of manufacturing methods that correspond to the TFT 100D of FIG. 15(a). FIGS. 16(a2) to 16(d2), 17(a2), and 17(b2) are cross-sectional views of a method of forming the gate/source intersection 200D corresponding to FIG. 15(b). FIGS. 16(a3) to 16(d3), 17(a3), and 17(b3) are cross-sectional views of a method of forming the auxiliary capacitance unit 300D corresponding to FIG. 15(c). FIGS. 16(a4) to 16(d4), 17(a4), and 17(b4) are cross-sectional views of a method of forming the gate terminal 400D corresponding to FIG. 15(d).

First, the gate wiring line 6, the gate electrode 6a, and the first auxiliary capacitance electrode 12 are formed over the substrate 1. The lower gate insulating layer 7a is formed over the gate wiring line 6, the gate electrode 6a, and the first auxiliary capacitance electrode 12. The first SOG insulating layer 17 is formed over the lower gate insulating layer 7a by the method mentioned above, and the upper gate insulating layer 7b is formed over the first SOG insulating layer 17 (refer to FIG. 11).

Next, the oxide semiconductor film is formed over the upper gate insulating layer 7b by sputtering. Then, the oxide semiconductor layer is patterned by a known method, and as shown in FIG. 16(a1), the oxide semiconductor film 9 is formed so as to overlap the gate electrode 6a when seen from a direction normal to the substrate 1. Furthermore, as shown in FIG. 16(a3), the oxide semiconductor layer 9a is formed so as to overlap with the first auxiliary capacitance electrode 12 when the substrate 1 is seen from a direction normal to the substrate 1. The oxide semiconductor layer 9 is not formed in the region shown in FIGS. 16(a2) to 16(a4).

Then, as shown in FIGS. 16(b1) to 16(b4), an etching stopper film 11′ was formed over the upper gate insulating layer 7b and the oxide semiconductor layer 9 by the CVD method or the like.

Next, as shown in FIGS. 16(c1) to 16(c4), the second SOG insulating layer 27 is formed by the spin coating method, photolithography, and the like. As shown in FIG. 16(c1), the second SOG insulating layer 27 has an opening 27u that overlaps the gate electrode 6a when seen from a direction normal to the substrate 1. Within the opening 27u, the island-shaped second SOG insulating layer 27 is formed, and the second SOG insulating layer 27 overlaps the channel region of the oxide semiconductor layer 9 when the island-shaped second SOG insulating layer 27 is seen from a direction normal to the substrate. Furthermore, as shown in FIG. 16(c3), the second SOG insulating layer 27 has an opening 27v formed therein that overlaps the first auxiliary capacitance electrode 12 when seen from a direction normal to the substrate 1. The first SOG insulating layer 27 is not formed in the region shown in FIG. 16(b4).

Next, as shown in FIGS. 16(d1) to 16(d4), the etching stopper film 11′ and the upper gate insulating layer 7b are patterned by a known method. As a result, as shown in FIG. 16(d1), when seen in a direction normal to the substrate 1, an island-shaped etching stopper layer 11 that overlaps the channel region of the oxide semiconductor layer 9 is formed. In both sides of the etching stopper layer 11, openings 11u that electrically connect the source electrode 8s and the drain electrode 8d to the oxide semiconductor layer 9 mentioned later are formed. The region shown in FIG. 16(d2) has the etching stopper layer 11 between the upper gate insulating layer 7b and the second SOG insulating layer 27. Furthermore, the region shown in FIG. 16(d3) has the etching stopper layer 11 having the opening 11v formed therein, thus exposing the oxide semiconductor layer 9a. In the region shown in FIG. 16(d4), the etching stopper layer 11 is not formed, and the upper gate insulating layer 7b is exposed.

Then, as shown in FIGS. 17(al) to 17(a4), the source wiring line 8, the source electrode 8s, the drain electrode 8d, and the second auxiliary capacitance electrode 8x are formed by a known method. As shown in FIG. 17(a1), the source electrode 8s and the drain electrode 8d are respectively in contact with the oxide semiconductor layer 9. As shown in FIG. 17(a2), the source wiring line 8 is formed over the second SOG insulating layer 27. As shown in FIG. 17(a3), the second auxiliary capacitance electrode 8x that is in contact with the oxide semiconductor layer 9a is formed in the opening 11v. The second auxiliary capacitance electrode 8x overlaps the first auxiliary capacitance electrode 12 across the lower gate insulating layer 7a.

Then, as shown in FIGS. 17(b1) to 17(b3), a protective film (not shown) is formed over the source wiring line 8, the source electrode 8s, the drain electrode 8d, and the second auxiliary capacitance electrode 8x by the CVD method or the like. Furthermore, in the region shown in FIG. 17(b4), a protective film is formed over the upper gate insulating layer 7b. Next, the interlayer insulating layer 14 is formed over the protective film using the photolithography method. The protective film is patterned using the interlayer insulating layer 14 as a mask. As a result, as shown in FIG. 17(b1), the contact hole CH1 is formed in the protective layer 13 and the interlayer insulating layer 14, and is formed over the drain electrode 8d, thus exposing a portion of the surface of the drain electrode 8d. Also, in the region shown in FIG. 17(b2), the protective layer 13 is formed over the source wiring line 8, and the interlayer insulating layer 14 is formed over the protective layer 13. Furthermore, as shown in FIG. 17(b3), the contact hole CH2 that exposes the surface of the second auxiliary capacitance electrode 8x is formed in the protective layer 13 and the interlayer insulating layer 14. Also, in the region shown in FIG. 17(b4), the protective layer 13, the lower gate interlayer insulating layer 7a, and the upper gate insulating layer 7b are simultaneously etched to form the contact hole CH3 in the protective layer 13 and the interlayer insulating layer 14. By forming the contact hole CH3, a portion of the gate wiring line 6 is exposed.

Then, as shown in FIGS. 15(a) to 15(d), the transparent pixel electrode 15 and the transparent connection wiring line 15a are formed over the interlayer insulating layer 14 by a known method. As shown in FIG. 15(a), the transparent pixel electrode 15 and the drain electrode 8d are electrically connected in the contact hole CH1. As shown in FIG. 15(c), the transparent pixel electrode 15 and the second auxiliary capacitance electrode 8x are electrically connected in the contact hole CH2. As shown in FIG. 15(d), the transparent connection wiring line 15a and the gate wiring line 6 are electrically connected in the contact hole CH3. The transparent pixel electrode 15 is not formed over the interlayer insulating layer 14 in a region shown in FIG. 10(b).

In the above manner, the semiconductor devices 1000A to 1000D in which a drop in the auxiliary capacitance value is mitigated due to the etching stopper layer can be obtained.

### INDUSTRIAL APPLICABILITY

The embodiments in the present invention can be widely applied to semiconductor devices provided with a thin film transistor and an auxiliary capacitance over a substrate. In particular, this invention can be appropriately used in a display device having thin film transistors such as an active matrix substrate, and in a display device that is provided with semiconductor devices.

### DESCRIPTION OF REFERENCE CHARACTERS

1 substrate

6 gate wiring line

6a gate electrode

8 source wiring line

8s source electrode

8d drain electrode

8x, 12 auxiliary capacitance electrode

9 oxide semiconductor layer

11 etching stopper layer

11u, 11v opening

15 transparent pixel electrode

15a transparent connection wiring line

CH1, CH2, CH3 contact hole

1000A semiconductor device

1: A semiconductor device, comprising: a substrate; and a thin film transistor, an auxiliary capacitance unit, a source wiring line, and a gate wiring line that are supported by said substrate,
wherein the thin film transistor includes:
a gate electrode formed of a same conductive film as the gate wiring line;
a first insulating layer formed on the gate electrode;
an oxide semiconductor layer formed on the first insulating layer;
a second insulating layer that is formed on the oxide semiconductor layer and that is in contact with a channel region of the oxide semiconductor layer; and
a source electrode and a drain electrode that are formed of a same conductive film as the source wiring line and that are electrically connected to the oxide semiconductor layer,
wherein the auxiliary capacitance unit includes:
a first auxiliary capacitance electrode formed of the same conductive film as the gate wiring line;
a second auxiliary capacitance electrode formed of the same conductive film as the source wiring line; and
the first insulating layer positioned between the first auxiliary capacitance electrode and the second auxiliary capacitance electrode,
wherein the first insulating layer and the second insulating layer are formed between the gate wiring line and the source wiring line at a gate/source intersection where the gate wiring line and the source wiring line overlap in a direction normal to the substrate, and
wherein a distance between the first auxiliary capacitance electrode and the second auxiliary capacitance electrode is shorter than a distance between the gate wiring line and the source wiring line at the gate/source intersection.

2: The semiconductor device according to claim 1, further comprising:
an oxide layer formed of a same oxide film as the oxide semiconductor layer, below the second auxiliary capacitance electrode,
wherein the oxide layer and the second auxiliary capacitance electrode are in contact with each other.

3: The semiconductor device according to claim 1, wherein the distance between the first auxiliary capacitance electrode and the second auxiliary capacitance electrode is shorter than a distance between the gate electrode and the oxide semiconductor layer.

4: The semiconductor device according to claim 1, further comprising another insulating layer between the gate wiring line and the source wiring line at the gate/source intersection.

5: A method of manufacturing a semiconductor device including a thin film transistor and an auxiliary capacitance unit, comprising:
(A) forming a gate electrode and a first auxiliary capacitance electrode of a same conductive film over a substrate;
(B) forming a first insulating layer over the gate electrode and the first auxiliary capacitance electrode;
(C) forming an oxide semiconductor layer over the first insulating layer so as to overlap the gate electrode when seen in a direction normal to the substrate;
(D) forming a second insulating layer having a first opening that overlaps the first auxiliary capacitance electrode when seen from the direction normal to the substrate and a second opening that exposes a portion of the oxide semiconductor layer, by forming an insulating film over the oxide semiconductor layer and the first insulating layer and etching a portion of the first insulating layer and the insulating film; and
(E) forming a source electrode, a drain electrode, and a second auxiliary capacitance electrode of the same conductive film, the second auxiliary capacitance electrode being formed in the first opening, said step (E) including a step of electrically connecting the source electrode and the drain electrode to the oxide semiconductor layer in the second opening.

6: A method of manufacturing a semiconductor device including a thin film transistor and an auxiliary capacitance unit, comprising:
(A) forming a gate electrode and a first auxiliary capacitance electrode of a same conductive film, over a substrate;
(B) forming a first insulating layer over the gate electrode and the first auxiliary capacitance electrode;
(C) forming an oxide semiconductor layer and an oxide layer of a same oxide film, the oxide semiconductor layer being formed over the first insulating layer so as to overlap the gate electrode when seen in a direction normal to the substrate, the oxide layer being formed over the first insulating layer so as to overlap the first auxiliary capacitance electrode when seen in the direction normal to the substrate;
(D) forming a second insulating layer having a first opening that exposes the oxide layer and a second opening that exposes a portion of the oxide semiconductor layer; and
(E) forming a source electrode, a drain electrode, and a second auxiliary capacitance electrode of a same conductive film, the second auxiliary capacitance electrode being formed over the oxide layer in the first opening, said step (E) including a step of electrically connecting the source electrode and the drain electrode to the oxide semiconductor layer in the second opening.

7: The semiconductor device according to claim 1, wherein the oxide semiconductor layer includes an In—Ga—Zn—O semiconductor.

8: The method of manufacturing a semiconductor device according to claim 5, wherein the oxide semiconductor layer includes an In—Ga—Zn—O semiconductor.

9: The method of manufacturing a semiconductor device according to claim 6, wherein the oxide semiconductor layer includes an In—Ga—Zn—O semiconductor.
